(19) United States
(12) Patent Application Publication
(10) Pub. No.: US 2007/0195505 A1
(43) Pub. Date: Aug. 23, 2007

(54) Memory module device

(76) Inventors: Dominique Savignac, Ismaning (DE); Peter Gregorius, Munchen (DE); Hermann Ruckerbauer, Moos (DE); Simon Muff, Mering (DE)

Correspondence Address: EDELL, SHAPIRO & FINNAN, LLC, 1901 RESEARCH BOULEVARD, SUITE 400, ROCKVILLE, MD, 20850, US

(21) Appl. No.: 11/357,413

(22) Filed: Feb. 21, 2006

(51) Int. Cl. H05K 7/20

(52) U.S. Cl. 361/719

(57) ABSTRACT

A memory module device includes a printed circuit board, a plurality of memory modules and a buffer module. Lines are provided in or on the printed circuit board to connect the buffer module to the memory modules. The memory modules are combined at least partially to form memory module stacks.

### FIELD OF THE INVENTION

The invention relates to a memory module device including a printed circuit board, a plurality of memory modules which are provided on the printed circuit board, and a buffer module which is provided on the printed circuit board, lines which are provided in or on the printed circuit board electrically connecting the buffer module to the memory modules.

### BACKGROUND OF THE INVENTION

Improving the storage density and signal integrity of memory modules with printed circuit boards is a constant objective in order to be able to satisfy increased performance requirements in the future.

### SUMMARY OF THE INVENTION

The present invention provides a memory module device with performance data that is improved compared to conventional memory modules.

The memory module device according to the invention comprises a printed circuit board, a plurality of memory modules and a buffer module, lines which are provided in or on the printed circuit board electrically connecting the buffer module to the memory modules. The memory modules are combined at least partially to form memory module stacks (i.e., a “stacked” arrangement).

Combining the memory modules to form memory module stacks markedly increases both the storage density and the signal integrity.

In one preferred embodiment, the printed circuit board comprises at least one memory module recess, a memory module stack being provided in each memory module recess. In this embodiment, the memory module stack is accordingly “embedded” (integrated) into the printed circuit board, which makes a certain minimum thickness of the printed circuit board necessary. Alternatively, it is possible to provide the memory module stack on the surface of the printed circuit board.

If memory module recesses are provided for receiving memory module stacks, in one embodiment of the invention they have a terrace-shaped step, with at least one terrace-shaped step being provided with contacts for making contact with the memory modules. It is possible, for example, for a plurality, of terrace-shaped steps to be provided with contacts, and for contact to be made with in each case one memory module via the contacts of a specific terrace-shaped step.

In one embodiment of the invention, the contacts which are provided on the terrace-shaped steps are connected to a plurality of line planes which are arranged one on top of the other and are provided at least partially within the printed circuit board. In this embodiment, optimized signal flows can be generated which in turn entail a higher integration density of the memory module and lower signal interference on the electrical signals running in the lines.

The printed circuit board of the memory module according to the invention can be provided with a buffer module recess in which the buffer module is provided. By “countersinking” (integrating) the buffer module into the buffer module recess, it is possible to optimize the arrangement of the lines between the buffer module and the memory modules.

The memory module also has memory module contacts for making contact with the memory module. The memory module contacts can be configured as contact strips for use as a plug-type contact and/or as ball-grid contacts for use as a press contact. If ball-grid contacts are provided, in one preferred embodiment they are advantageously provided on the underside of the printed circuit board.

The memory modules of a memory module stack can be connected by heat sinks and an electrically nonconductive adhesive mass in such a way that each memory module stack is composed of an alternating sequence of memory modules and heat sinks. In this embodiment, heat which is generated within the memory modules can effectively be conducted away to the outside. The heat sinks can also be omitted, such that each memory module stack is composed of an alternating sequence of memory modules and adhesive mass.

In addition, the memory modules located within the memory module recesses or on the printed circuit board can be shielded from their surroundings by covers which cover the memory module recesses or are provided on the printed circuit board.

In one embodiment of the invention, the buffer module is arranged in a flip-chip arrangement on or in the printed circuit board. This has the advantage that the rear side of the buffer module can be coated over its surface with a heat sink (contact is made with the buffer module from below).

The memory module stacks are preferably arranged symmetrically around the buffer module. For example, the memory module stacks may be grouped in a star shape around the buffer module.

The above and still further objects, features and advantages of the present invention will become apparent upon consideration of the following detailed description of specific embodiments thereof, particularly when taken in conjunction with the accompanying drawings wherein like reference numerals in the various figures are utilized to designate like components.

### BRIEF DESCRIPTION OF THE DRAWINGS

FIG. 1 depicts a cross-sectional view of a first embodiment of the memory module device according to the invention.

FIG. 2 depicts a cross-sectional view of a second embodiment of the memory module device according to the invention.

FIG. 3 depicts a cross-sectional view of a third embodiment of the memory module device according to the invention.

FIG. 4 depicts a cross-sectional view of a fourth embodiment of the memory module device according to the invention.

FIG. 5 depicts a cross-sectional view of a fifth embodiment of the memory module device according to the invention.

FIG. 6 depicts a cross-sectional view of a sixth embodiment of the memory module device according to the invention.

FIG. 7 depicts a cross-sectional view of a seventh embodiment of the memory module device according to the invention.

FIG. 8 depicts a plan view of the embodiments of FIG. 7.

FIG. 9 depicts a cross-sectional view of the embodiment of FIG. 7 in a completely mounted state.

FIG. 10 depicts a cross-sectional view of an eighth embodiment of the memory module device according to the invention.

FIG. 11 depicts a cross-sectional view of a ninth embodiment of the memory module device according to the invention.

FIG. 12 depicts a plan view of the embodiment of FIG. 11.

FIG. 13 depicts a cross-sectional view of a tenth embodiment of the memory module device according to the invention.

FIG. 14 depicts a plan view of the embodiment of FIG. 13.

FIG. 15 depicts a cross-sectional view of the embodiment of FIG. 13 in a completely mounted state.

FIG. 16 depicts a cross-sectional view of the embodiment of FIG. 13 in a completely mounted state.

FIG. 17 depicts a plan view of an eleventh embodiment of the memory module device according to the invention.

FIG. 18 depicts a plan view of a twelfth embodiment of the memory module device according to the invention.

FIGS. 19a-c schematically depict storage concepts in which the memory module device according to the invention can be used.

FIGS. 20a-b schematically depict storage concepts in which the memory module device according to the invention can be used.

### DETAILED DESCRIPTION

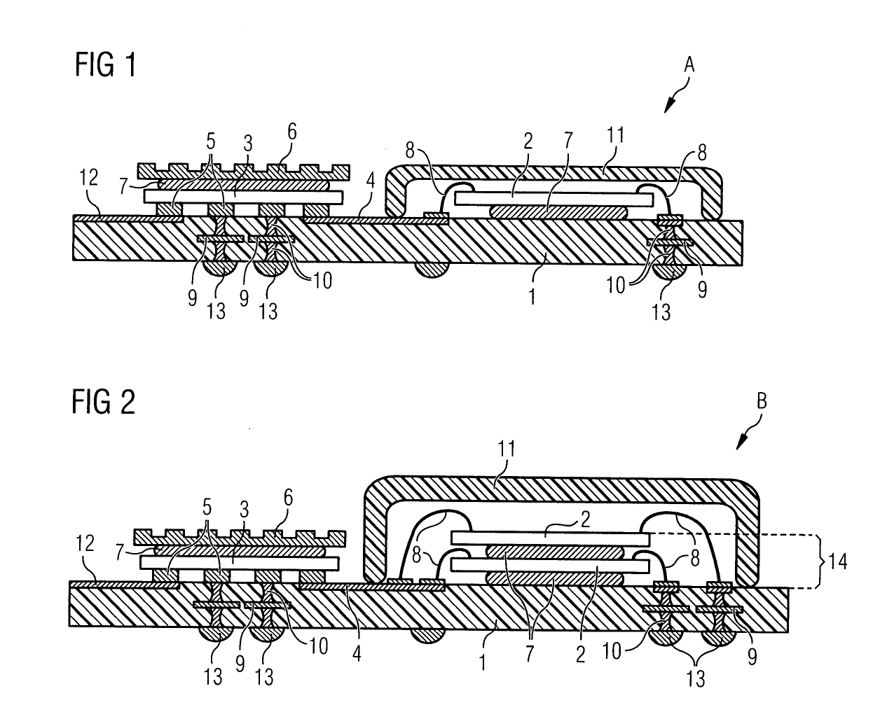

A first exemplary embodiment of the memory module device according to the invention is shown in FIG. 1. The memory module device A includes a printed circuit board 1, a memory module 2 and a buffer module 3. The buffer module 3 is electrically connected to the memory module 2 via lines 4. The buffer module 3 is arranged in a flip-chip arrangement on the printed circuit board 1, i.e., the rear side of the buffer module 3 forms and is aligned with the upper side of the memory module 2, permitting contact to be made with the buffer module 3 from below via corresponding connections 5. This makes it possible to provide a heat sink 6 on the rear side of the buffer module 3, i.e. on its upper side, which is thermally connected to the memory module 2 via a soldered connection 7, and serves the purpose of effectively outputting heat generated within the memory module 2 to the surroundings. Instead of the soldered connection 7 it is also possible to use heat sinks, adhesive masses or combinations of these alternatives. The memory module 2 is also mechanically connected to the printed circuit board 1 by a soldered connection 7 and is electrically connected to the lines 4 via bonding wires 8. Electrical lines 9 are likewise provided within the printed circuit board 1, and some of them are electrically connected to the buffer module 3 and some to the memory chip 2 via connections 10. The memory chip 2 is shielded from the surroundings by a housing 11. Some of the electrical connections of the memory module device A are in the form of strip-shaped memory module contacts 12 which are provided on the upper side of the printed circuit board 1, and some are in the form of ball-grid memory module contacts 13 which are provided on the underside of the printed circuit board 1. The strip-shaped memory module contacts 12 have the purpose of making contact by a plug-type connection, while the ball-grid-shaped memory module contacts 13 have the purpose of making contact by pressure (see FIG. 5). The advantage of such press contacts is improved routing of signals.

The memory module device B shown in FIG. 2 differs from the memory module device A shown in FIG. 1 in that two memory modules 2 are provided, and they are combined to form a memory module stack 14. The memory module stack 14 is composed of an alternating sequence of soldered connections 7 and memory modules 2. Providing such a memory module stack 14 results in an increased storage density of the memory module device B.

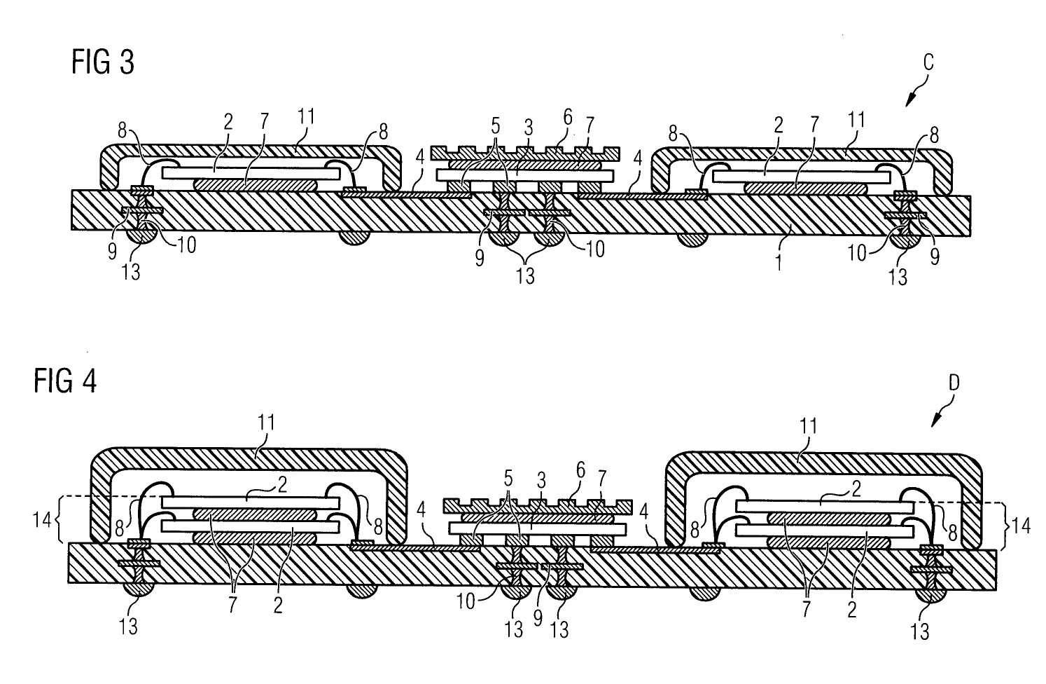

The memory module device C shown in FIG. 3 corresponds essentially to the memory module device A shown in FIG. 1, except for the difference that two memory modules 2 are provided, and these are arranged symmetrically around the buffer module 3. A further difference is that contact is made exclusively with the memory module device C by ball-grid memory module contacts 13.

The memory module device D which is shown in FIG. 4 differs from the memory module device C show in FIG. 3 in that four memory modules 2, instead of two, are provided on the printed circuit board 1, two memory modules 2 being combined in each case to form memory module stacks 14.

FIG. 5 shows how the memory module device C can be mounted on a motherboard by clamps 15. A pressure is exerted via the clamps 15 so that press contacts are formed between the ball-grid memory module contacts 13 and corresponding contacts 17 which are provided on the motherboard 16. The contacts 17 are in turn connected to conductor tracks 18 which are provided within the motherboard 16.

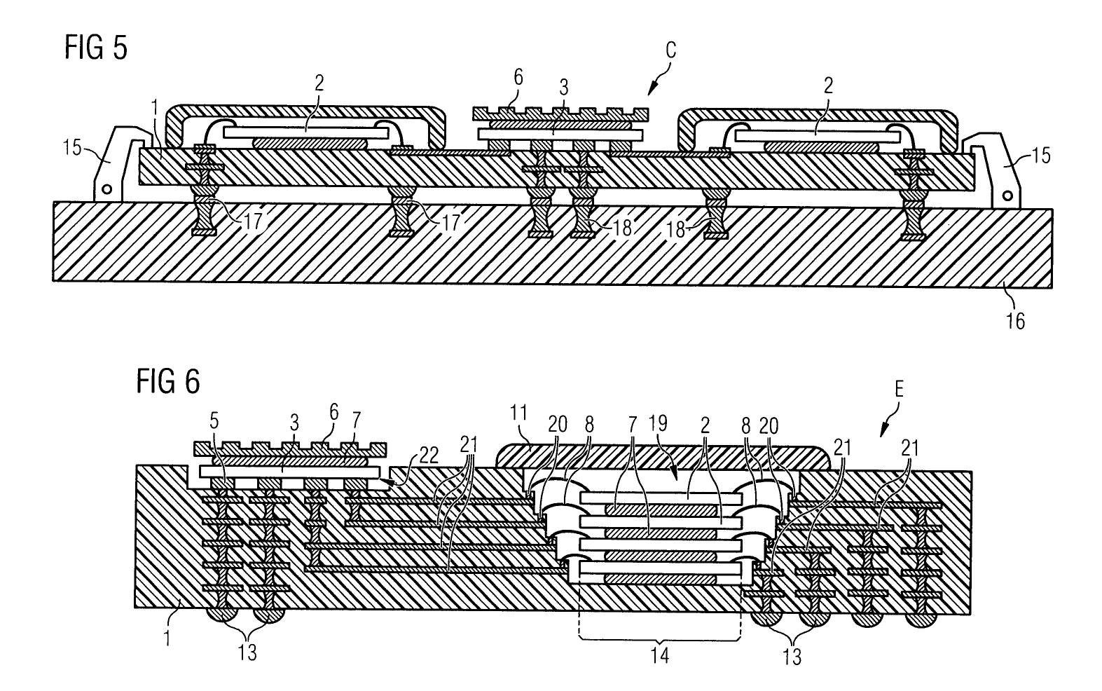

The memory module device E which is shown in FIG. 6 has a memory module recess 19 in which a memory module stack 14 is provided. The memory module stack 14 is composed of an alternating sequence of memory modules 2 and of soldered connections 7. The memory module recess 19 has a terrace-shaped or stepped configuration, with each step being provided with contacts 20, and with contact being made in each case with one of the memory modules 2 by bonding wires 8 via the contacts 20 of a specific terrace-shaped or stepped configuration. The contacts 20 are each connected to line planes 21 which are each arranged one on top of the other and either extend onto the underside of the printed circuit board 1 to ball-grid memory module contacts 13 or to connections 5 for making contact with the buffer module 3, i.e. are electrically connected thereto. The memory module recess 19 is covered with a cover 11 so that the memory modules 2 are shielded from the surroundings. Furthermore, a buffer module recess 22 in which the buffer module 3 is “countersunk” is provided in the printed circuit board 1. The advantage here is that the lines between the buffer buffer module 3 and the memory modules 2 can be made shorter on the corresponding printed circuit board plane owing to optimum wiring, and at the same time the overall height of the module can be reduced. The advantage of the memory module device E is that the storage density of the memory module device can be greatly increased compared to conventional solutions.

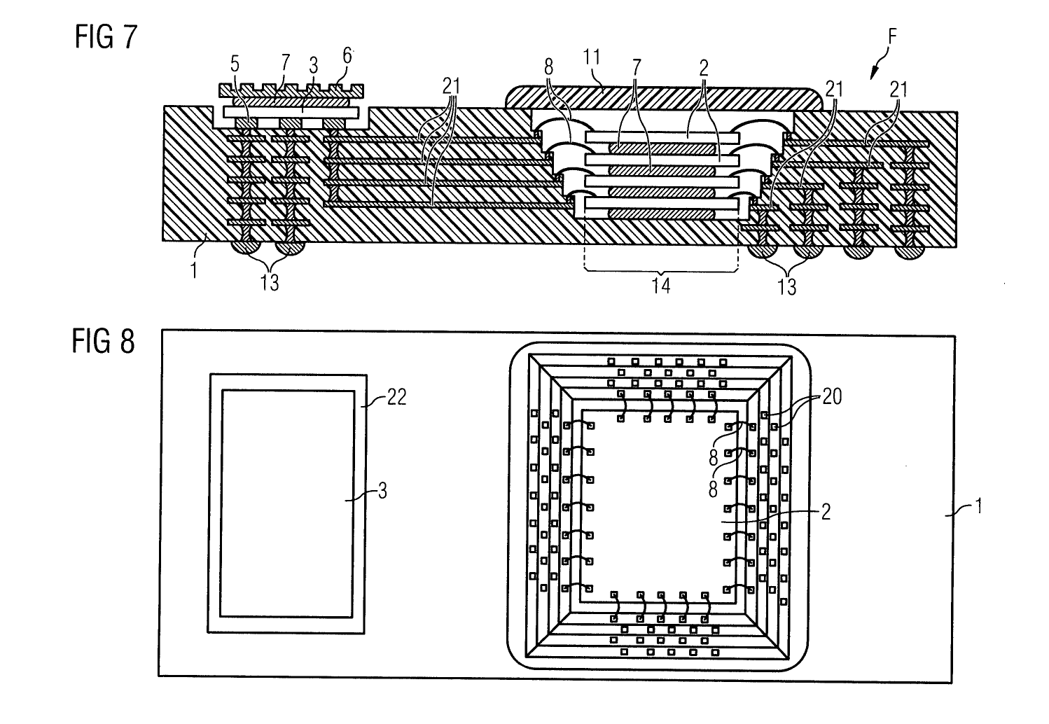

The memory module device F shown in FIG. 7 corresponds to the memory module device E, apart from line planes 21 which are configured differently.

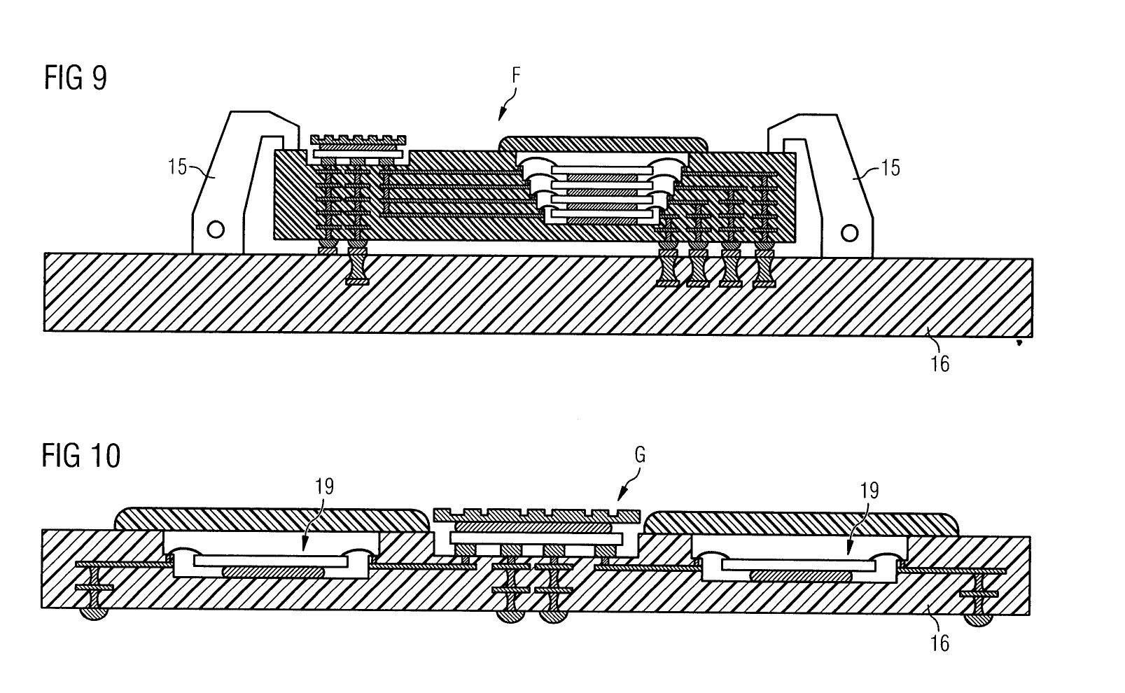

The memory module device F shown in FIG. 7 is shown in plan view in FIG. 8, and is further shown mounted to a motherboard 16 in FIG. 9.

The memory module device G shown in FIG. 10 corresponds with the memory module device C shown in FIG. 3, with the exception that memory module recesses 19 are provided in the printed circuit board 1 and the memory modules 2 are provided within the recesses 19. This permits reduced overall height of the module to be achieved.

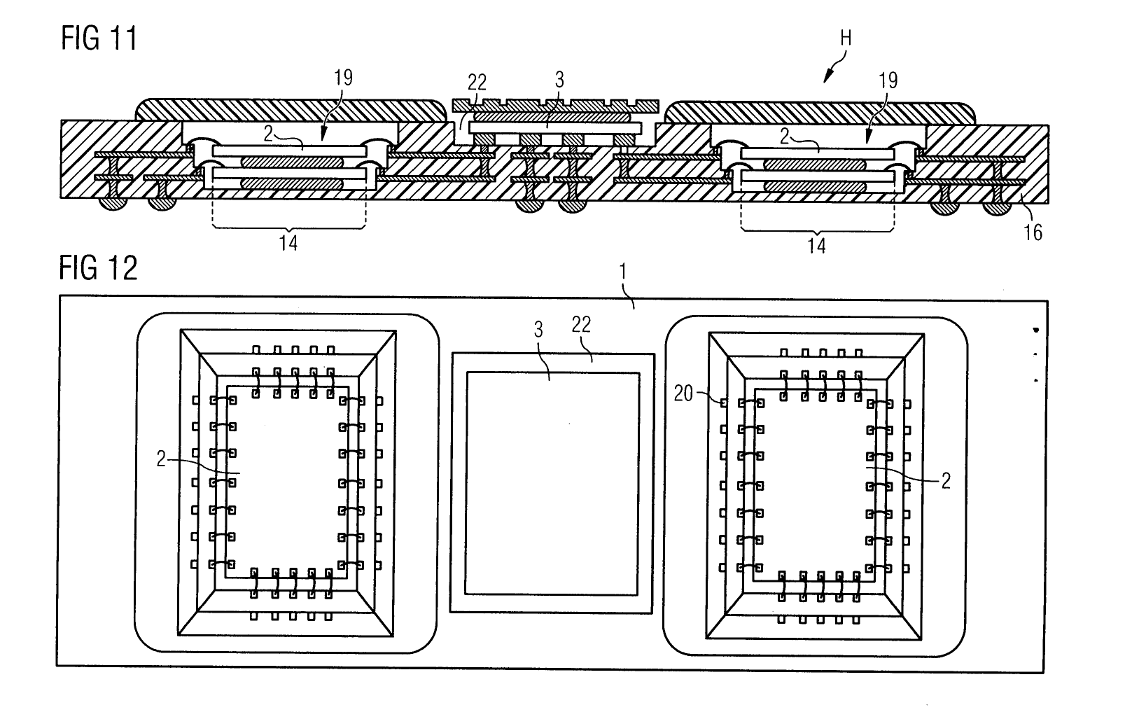

The memory module device H shown in FIG. 11 corresponds with the memory module device G shown in FIG. 10, with the exception that in each case memory module stacks 14 are provided within the memory module recesses 19. As a result, the wiring within the printed circuit board 1 differs consequently from the wiring shown in FIG. 10. FIG. 12 shows a plan view of the memory module device H.

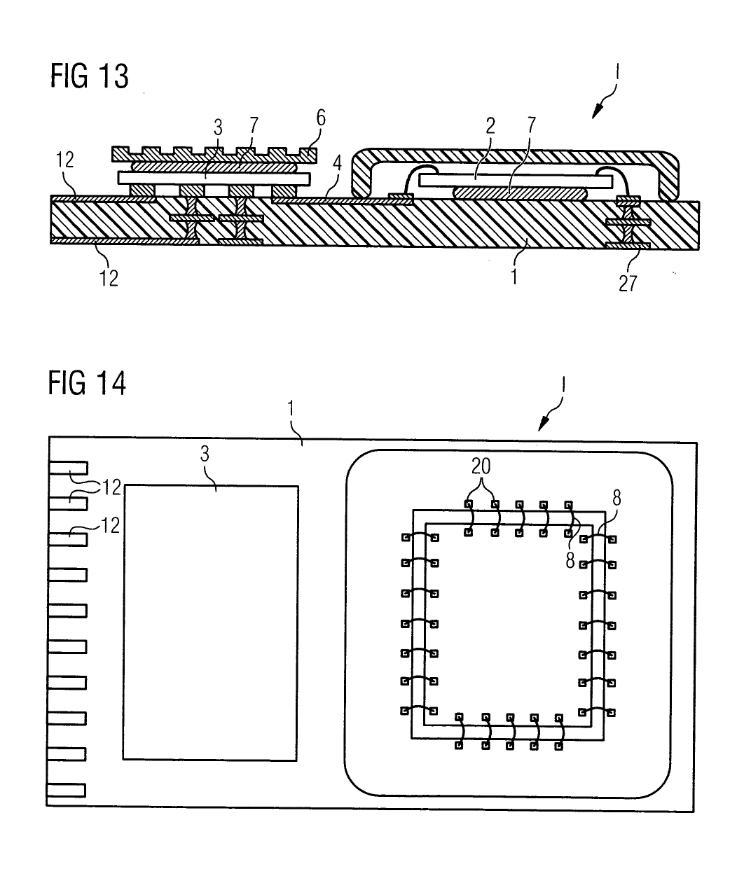

The memory module device I shown in FIG. 13 is similar to the memory module device A shown in FIG. 1 and differs from it in that, instead of ball-grid memory module contacts 13, only strip-shaped memory module contacts 12 are provided both in the upper side and on the underside of the printed circuit board 1.

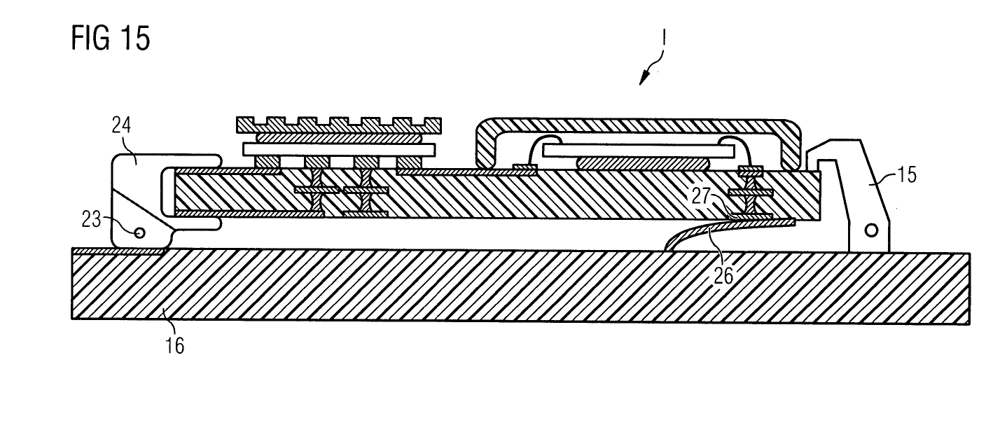

FIG. 14 shows a plan view of the memory module device I. FIG. 15 shows how the memory module device I can be mounted on a motherboard 16. In this embodiment, the memory module device I is plugged into a plug-type connection 24 which, in order to facilitate mounting, can be pivoted about an axle 23 so that the memory module device I can be introduced into the plug-type connection 24 from above. The memory module device I is then folded downward and held by the clamp 15, a spring 25, which serves at the same time for making contact with a contact 26 located on the underside, generating the necessary counterpressure.

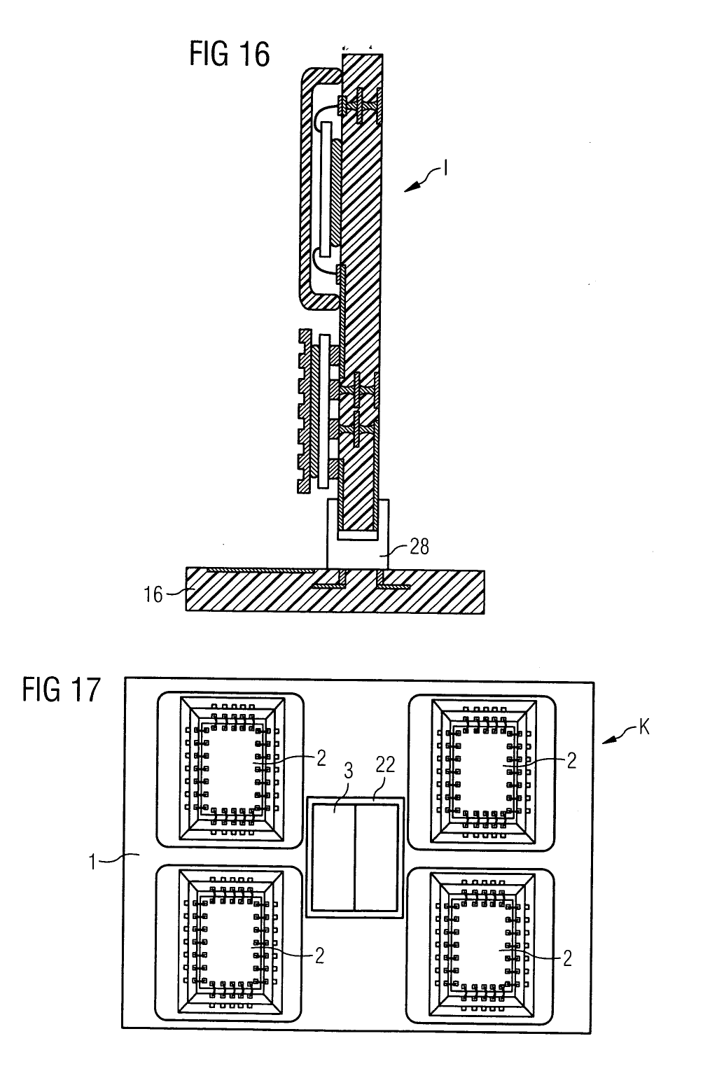

Alternatively, contact can also be made with the memory module device I merely by a plug-type connection 28, as indicated in FIG. 16.

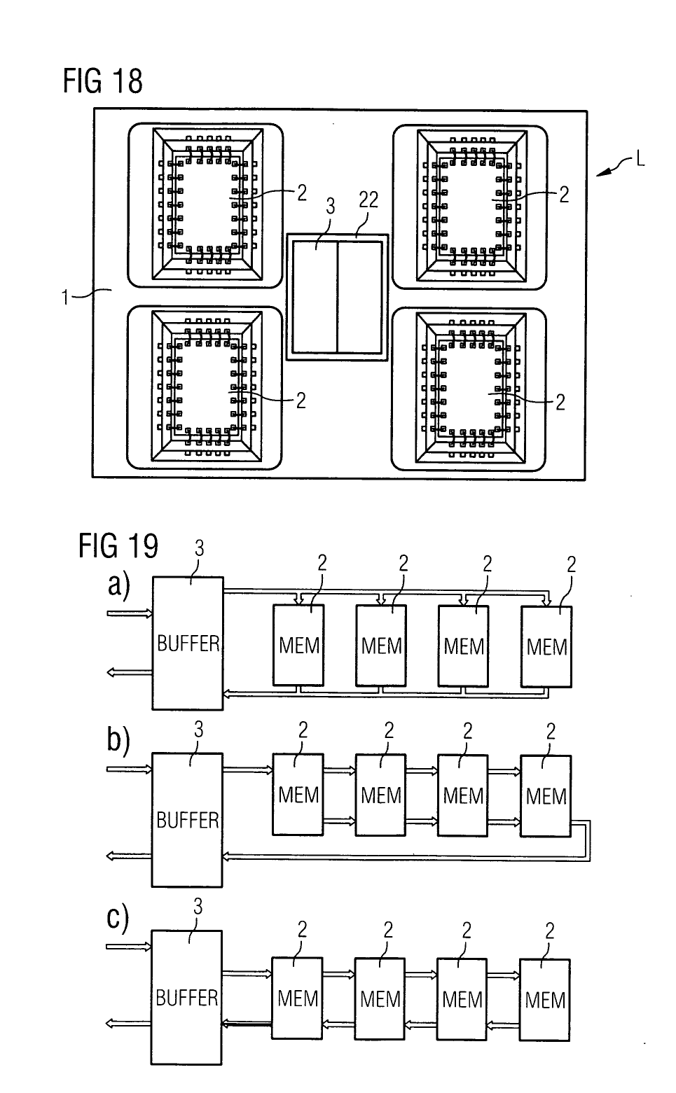

The memory module device K shown in FIG. 17 corresponds essentially to the memory module device G shown in FIG. 10, with the exception that four memory modules 2, and not two are provided, and these are arranged in a star shape around the buffer module 3. In an analogous fashion, the memory module device L shown in FIG. 18 is similar to the memory module device A shown in FIG. 11, with the exception that four memory module stacks 14, and not two, are provided and are arranged in a star shape around the buffer module 3.

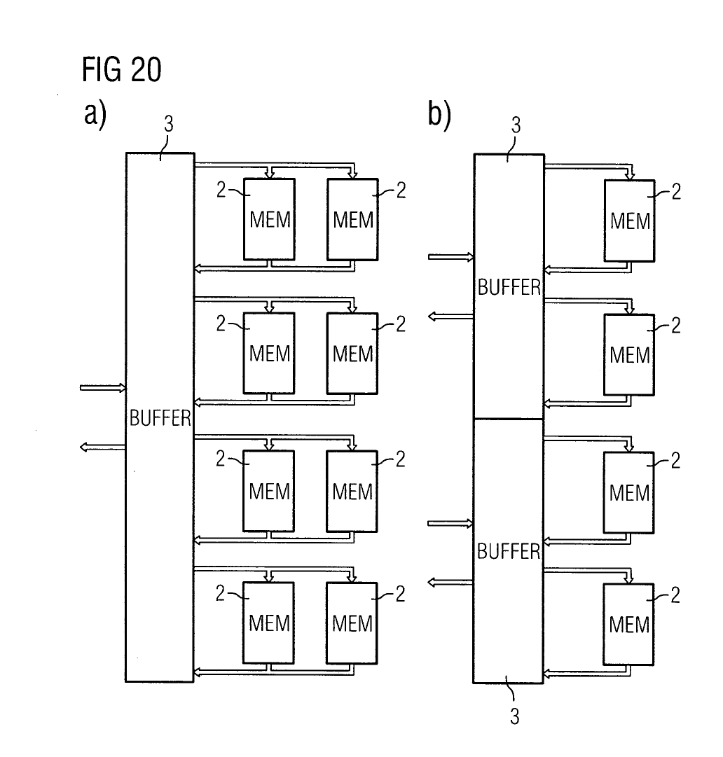

The electrical arrangements (illustrated in FIGS. 19a) to c)) of the memory module devices with buffers correspond to the physical arrangements according to FIGS. 1-17. The physical arrangements according to FIGS. 3, 4, 11, 12 and 17 are particularly advantageous for the electrical arrangements according to FIGS. 20 a) and b). The advantage of this arrangement is that the electrical routing of the signals is reflected in the physical routing of the signals and thus ultimately in the arrangement of the modules.

The memory module devices described above provide a buffer with a specific high speed signal routing with symbol rates >1 Gbit/s/lane. The embodiments according to the invention optimize the signal routing from buffer to memory. The signal routing from buffer module to memory controller is also optimized. In particular, short signal paths, intersection-free signal routing—which is at the same time optimized in terms of area—and the best possible arrangement of supply lines are used. The memories may be arranged on the memory module device in a planar fashion or in the form of a terrace. Optimum line routing to the buffer module is obtained for both arrangement variants.

Both planar arrangement of the memory module devices according to FIGS. 1 or 3 and the arrangement in a terrace according to FIGS. 6 or 7 permit a “stacked” variant. The term “stacked” refers herein to the stacked arrangement of the memory module devices which are shown, for example, in FIGS. 2 or 6. The number of stacked memory modules is limited here only by the technical feasibility. For example, four memory modules can be implemented in a “stacked” arrangement.

The buffer module is responsible for communication between the memory controller (MC) and memory module. The data communication between the MC and memory module is preferably configured as a serial data transmission (a “high speed serial link”). As a result, the communication between the memory controller and the memory module differs from the customarily used parallel databus (e.g., DDR2/DDR3).

Other buffer solutions require a re-drive of the data from the MC/to the MC on the buffer module or on the memory module. The arrangement according to the figures eliminates the need for a re-drive of the data from the MC/to the MC. From the point of view of the MC, the system behaves equivalently compared to other more complex buffer solutions.

The arrangement illustrated in FIG. 1 shows planar signal routing between the buffer and memory module and from the buffer to the edge of the memory module. This is advantageous in particular in the sense of signal integrity since no additional vias and thus reflections additionally disrupt the signal.

FIG. 5 illustrates a preferred embodiment for mounting the memory module. The memory module is implemented as a ball-grid. The “balls” on the rear side of the module are pressed onto the contact faces of the main board. This technology is not known for conventional processors, for memory modules, but leads to improved signal routing at high data rates.

However, the present invention can also include customary mounting techniques by plug-type connections (plugs). FIGS. 13, 14, 15 and 16 show corresponding exemplary embodiments.

The general electrical arrangement of the buffer and memory cell is illustrated in FIG. 19. Optimum connection of the memory modules to the buffer is possible with a parallel connection, loop-forward (chain) arrangement or loop-back arrangement.

The invention permits modern packet-oriented data protocols to be used between the buffer and MC while at the same time using a standard interface between the buffer and memory module. It is particularly advantageous here to use interfaces on the memory module as is customary in graphic applications (e.g., GDDR3). However, any other standard interfaces can also be used between the buffer and memory (e.g., DDR2/DDR3). Pure point-to-point or point-to-multiple-point connections can also be used between the buffer and memory module in order to optimize the data communication further. It is not absolutely necessary to implement a standardized interface between the buffer and memory.

A further advantage of the invention is the possibility of cooling the buffer module on the rear side to an optimum degree. Since the buffer modules which are used according to the invention have a high power drain, the mounting of the buffer on the memory module using flip-chip technology is advantageous. The rear side of the buffer can thus be provided with an additional heat sink according to FIG. 1.

Using the flip-chip technology for the buffer is advantageous in particular with respect to the signal routing and the signal integrity.

Contrary to customary buffer solutions (registers), the buffer has a parallel-serial and serial-parallel conversion. Techniques of the rapid serial data transmission are applied (e.g., symbol synchronization, frame synchronization, clock generation etc.). A digital monitoring unit prepares the data for communication between the MC and memory module.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

List of Reference Symbols

1 Printed circuit board
2 Memory module
3 Buffer module
4 Line
5 Connection
6 Heat sink
7 Soldered connection
8 Bonding wire
9 Line
10 Connection
11 Housing
12 Memory module contact
13 Memory module contact
14 Memory module stack
15 Clamp
16 Motherboard
17 Contact
18 Conductor track
19 Memory module recess
20 Contact
21 Line plane
22 Buffer module recess
23 Axle
24 Plug-type connection
26 Spring
27 Contact
28 Plug-type connection
A-L Memory module device

What is claimed:

1. A memory module device comprising:
a printed circuit board;
a plurality of memory modules;
a buffer module; and
lines provided in or on the printed circuit board to electrically connect the buffer module to the memory modules;
wherein the memory modules are combined at least partially to form memory module stacks.

2. The memory module device of claim 1, wherein the printed circuit board includes at least one memory module recess, and a memory module stack is provided in the at least one memory module recess.

3. The memory module device of claim 2, wherein the at least one memory module recess has a stepped configuration including a plurality of steps, with at least one step of the recess being provided with contacts to make contact with the memory modules.

4. The memory module device of claim 3, wherein each step of the recess is provided with a contact to make contact with a corresponding memory module of the memory module stack.

5. The memory module device of claim 3, wherein the contacts provided on the at least one step of the recess are connected to a plurality of line planes, the line planes being arranged one on top of each other and disposed at least partially within the printed circuit board.

6. The memory module device of claim 1, wherein the printed circuit board includes a buffer module recess in which the buffer module is provided.

7. The memory module device of claim 1, further comprising memory module contacts to make contact with the memory modules, wherein the memory module contacts comprise contact strips having at least one of a plug-type contact configuration and a ball-grid contact configuration so as to be used as a press contact.

8. The memory module device of claim 7, wherein the contact strips include a selected number of ball-grid contacts that are provided on an underside of the printed circuit board.

9. The memory module device of claim 1, wherein the memory modules of a memory module stack are connected to one another by heat sinks such that each memory module stack includes an alternating sequence of memory modules and heat sinks.

10. The memory module device of claim 1, wherein the memory modules are shielded by covers.

11. The memory module device of claim 1, wherein the buffer module is arranged in a flip-chip arrangement on or in the printed circuit board.

12. The memory module device of claim 11, wherein a heat sink is provided on a rear side of the buffer module.

13. The memory module device of claim 1, wherein the memory module stacks are arranged in a symmetrical configuration around the buffer module.
